(19) United States
(12) Patent Application Publication
(10) Pub. No.: US 2011/0064401 A1
(43) Pub. Date: Mar. 17, 2011

(54) COUPLING AND ACCESSORY SYSTEM FOR ELECTRONIC DEVICES

(76) Inventor: ALEXANDER P. DESORBO, Woodbury, CT (US)

(21) Appl. No.: 12/880,652

(22) Filed: Sep. 13, 2010

Related U.S. Application Data
(60) Provisional application No. 61/234,418, filed on Sep. 11, 2009.

(51) Int. Cl. G03B 17/00; F21V 21/00; H01F 7/02; H05K 5/02; B23P 17/04

(52) U.S. Cl. 396/419; 362/398; 248/206.5; 312/223.1; 29/428

(57) ABSTRACT

A coupling and accessory system for an electronic device includes an enclosure configured to encompass at least a portion of the electronic device. The enclosure includes a land area having a magnetically active region or a magnetically attractive region. A coupling device also has a magnetically active region or a magnetically attractive region, such that the enclosure and the coupling device are magnetically attracted and attached to one another when the enclosure is brought into close association with the coupling device. The coupling device may further include at least one enhanced engagement feature for inhibiting mutual sliding or rotation between the coupling device and the enclosure during magnetic attachment of the one to the other.

### CROSS REFERENCE TO RELATED APPLICATIONS

This application claims the benefit of U.S. Provisional application Ser. No. 61/234,418, filed on Sep. 11, 2009, and herein incorporated by reference in its entirety.

### FIELD OF THE INVENTION

The present invention relates generally to a magnetically operable coupling and attachment system for devices, and deals more particularly with a magnetically operable coupling and accessory system for the support and utilization of hand-held electronic devices, such as i-phones®, i-pod®, i-pad®, cameras, camcorders and other audio and visual recording and playback devices and the like.

### BACKGROUND OF THE INVENTION

As technology and innovation march forward, electronic devices are designed to be ever smaller in both size and weight, while at the same time having an increased functionality as compared to previously known devices.

Examples of smaller, lighter and more advanced electronic devices, particularly hand-held electronic devices, include the increasingly popular “smart phone” and “pocket camera” product genres. These devices include integrated memory for storing data including image data, and offer ever-increasing functionality to address a variety of applications including still and live motion photography and video recordings.

While the quality of the pictures and/or recordings made by such devices are quite high in the abstract, their reduced size and weight do make these devices subject to the corrupting influences of ‘shake’ and other associated and oscillating human movement.

Moreover, their small ‘footprint’ itself makes the handling, support and utilization of such hand-held electronic devices problematic, oftentimes resulting in poor quality still pictures and/or video recordings, despite the abstract quality of their integrated components, camera elements and the like.

The seemingly limitless functionality of these devices often requires the device to be stably and releasably mounted to another surface—such as the windshield of an automobile to take advantage of a GPS map and direction function. Current methods either require the device to be used without a protective cover or employ a protective cover that compromises the small size and portability of the device.

The size of these devices and their inherent inability to provide for accessories such as handles, grips, lights, microphones, etc., have led to numerous attempts to support and augment the operation of hand-held electronic devices by way of complex and cumbersome structural clamps, screws and platforms, however these constructs suffer from excessive size and weight that detract from performance.

### SUMMARY OF THE INVENTION

With the foregoing problems and concerns in mind, it is the general object of the present invention to provide a magnetically operable coupling and accessory system for the support and utilization of electronic devices.

It is one object of the present invention to provide a magnetically operable coupling and accessory system for the support and utilization of hand-held electronic devices.

According to an embodiment of the present invention, a coupling and accessory system for an electronic device includes an enclosure configured to encompass at least a portion of the electronic device. The enclosure has at least one area defined thereon, which is a magnetically active region or a magnetically attractive region. This embodiment of the inventive system further includes a coupling device, which has at least one of a magnetically active region or a magnetically attractive region corresponding to the at least one area of the enclosure, such that the enclosure and the coupling device are magnetically attracted and attached to one another when the enclosure is brought into close association with the coupling device. Additionally, when brought together, the enclosure and coupling device are mechanically engaged so as to inhibit a sliding disengagement of the enclosure from the coupling device while the enclosure and the coupling device are magnetically attached to one another.

According to an embodiment of the present invention, a case for a handheld device includes an aperture for providing access to a magnetically active or attractive area formed on an enclosure of the handheld device. Via the aperture, a coupling device containing a magnetically active or attractive area may be engaged with the corresponding area formed on the enclosure of the device.

According to an embodiment of the present invention, a coupling and accessory system for an electronic device includes an enclosure configured to encompass at least a portion of the electronic device. The enclosure has at least one area defined thereon, which is a magnetically active region or a magnetically attractive region. This embodiment of the inventive system further includes a coupling device, which has at least one of a magnetically active region or a magnetically attractive region corresponding to the at least one area of the enclosure, such that the enclosure and the coupling device are magnetically attracted and attached to one another when the enclosure is brought into close association with the coupling device. Additionally, when brought together, the enclosure and coupling device are mechanically engaged so as to inhibit a sliding disengagement of the enclosure from the coupling device while the enclosure and the coupling device are magnetically attached to one another. This embodiment of the invention further includes a case interposed between the enclosure and the coupling device. The case includes an aperture aligned with the magnetically active or attractive area on the enclosure, and with the magnetically active or attractive area on the coupling device, so that the enclosure and the coupling device are mechanically engaged via the aperture of the case so as to capture the case. Optionally, the case may include a flexible member for engaging the enclosure.

According to an embodiment of the present invention, a method is provided for mounting a handheld device to a support, including the following steps. The method includes a step of providing an enclosure configured to encompass at least a portion of the electronic device and having at least one area defined thereon, wherein the area is a magnetically active region or a magnetically attractive region. The method further includes steps of encompassing the device within the enclosure; providing a magnetic coupling device, which includes a mechanical attachment structure; fastening the mechanical attachment structure to the support; and magnetically attaching the enclosure to the magnetic coupling device.

According to an embodiment of the present invention, an enclosure for an electronic device includes a case configured to encompass at least a portion of the electronic device. The case includes at least one magnetically active or magnetically attractive region for magnetic attachment to a corresponding magnetically attractive region or magnetically active region of a complementary coupling device.

According to an embodiment of the present invention, a coupling device for use with a complementary enclosure includes a mechanical attachment structure and a magnetically active or magnetically attractive surface connected with the mechanical attachment structure. The magnetically active or magnetically attractive surface includes at least one enhanced engagement feature for restraining sliding motion of the complementary enclosure.

### BRIEF DESCRIPTION OF THE DRAWINGS

Further objectives and advantages of the invention will become more apparent from the following description and claims, as from the accompanying drawings, wherein:

FIG. 1 is an component view of a magnetically operable coupling and accessory system for the support and utilization of hand-held electronic devices, in accordance with one embodiment of the present invention;

FIG. 2 illustrates the mating of various components of the magnetically operable coupling and accessory system, shown in FIG. 1;

FIGS. 3 and 4 illustrate the attachment of a coupling device of the magnetically operable coupling and accessory system, as functionally integrated with a tripod assembly, according to one embodiment of the present invention;

FIGS. 5 and 6 illustrate the mating of a hand-held electronic device with the coupling device shown in FIGS. 3 and 4, in accordance with one embodiment of the present invention;

FIG. 7 is an illustrative view of the magnetically operable coupling and accessory system of FIGS. 5 and 6, in use;

FIG. 8 illustrates one possible accessory utilization of the coupling device, according to one embodiment of the present invention;

FIGS. 9 and 10 illustrate tactile protuberances and surface gradients that may be embossed or otherwise formed on one or more components of the magnetically operable coupling and accessory system, in accordance with the present invention; and

FIG. 11 illustrates several additional and integrated accessory utilizations of the magnetically operable coupling and accessory system, in accordance with yet further alternative embodiments of the present invention.

FIG. 12 illustrates a handheld device enclosure and a magnetic coupling device, according to another embodiment of the invention.

### DETAILED DESCRIPTION OF EMBODIMENTS

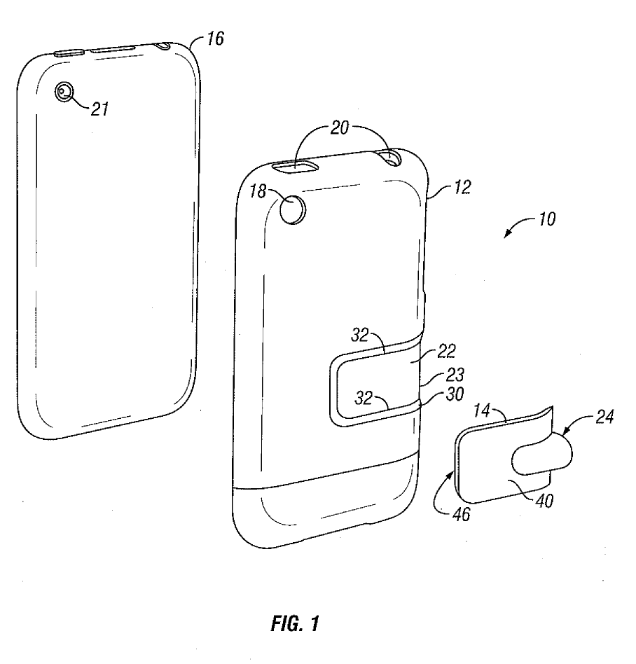

The base components of a magnetically operable coupling and accessory system 10 are shown in FIG. 1. As depicted therein, FIG. 1 illustrates the system 10 including a case, cover, or coupling enclosure 12 and a coupling device 14 which, in the embodiment shown in FIG. 1, are used with a hand-held electronic device, such as a known i-phone® device 16 shown for purposes of illustration only.

It should be noted that although a hand-held smart phone device may be shown in the associated drawings figures, the present invention is not so limited in this regard. Indeed, the magnetically operable coupling and accessory system 10 may be equally adapted and utilized with any electronic, or non-electronic, device, without departing from the broader aspects of the present invention.

Still referring to FIG. 1, it will be appreciated that the case 12 has been designed to conform to the outer dimension of the hand-held device 16, including having requisite openings, e.g. 18 and 20, to permit access to a camera lens, or data exchange and audio ports, or other controls, inputs or outputs. That is, the case or cover 12 thus at least partially encloses the device 16 without inhibiting use of the device 16. In various embodiments, as described below, the case 12 may enhance use of the device 16 by improving stability, ergonomics, or aesthetic appearance of the device.

The case 12 is envisioned to be fabricated from a resilient, preferably rigid material, such as hardened plastic, or metal, so as to give additional structural support to the hand-held device 16 when coupled to the coupling device 14, and thereafter, if desired, to any accessory device. When fabricated from a rigid material, it is considered that the case 12 should be formed as a two-piece case with two end portions 12a, 12b, wherein the end portions are snapped or squeezed together from ends of the hand-held device 16. However, within the scope of the invention it is feasible to construct the case 12 as a single piece including a substantially rigid portion integral with one or more flexible members for engaging the device 16 in a snap-on or slip-on manner.

A land 22 is formed in the body of the case 12, and is preferably formed from any ferrous material, or the like, which is capable of attraction to, and by, any known magnet. It will be readily appreciated that the land 22 may be a stand-alone insert that is fixedly or removably integrated with the case 12, or alternatively, the land 22 may be an integrally formed portion of the case 12, or formed directly as part of the device enclosure 16, without departing from the broader aspects of the present invention.

The coupling device 14 illustrated in FIG. 1 can be made from a magnetically active material, of any type or composition, provided it is capable of attraction to, and by, the material of the land 22. The size, shape and configuration of the coupling device 14 may also take any form provided that it is capable of magnetically coupling device with the land 22. As will be described in more detail later, the coupling device 14 may be equipped with a mechanical attachment structure 24, which may be a threaded port for selective attachment to various accessory devices, or the like, although other attachment structures may be provided to the coupling device 14, as required by the particular use thereof.

It can readily be appreciated that the coupling device 14 can be constructed largely from non-magnetic or non-ferrous material, such as molded plastic, with the magnetic or ferrous component an integral part thereof.

Moreover, it can readily be appreciated that the magnetically operable coupling and accessory system may be adapted directly to the enclosure of the device itself and that the case 12 represents an aftermarket approach to an existing device. In other words, as an alternative to the exemplary embodiment presented in FIGS. 1 through 3, the land 22 may be formed directly on an enclosure of the hand-held device 16.

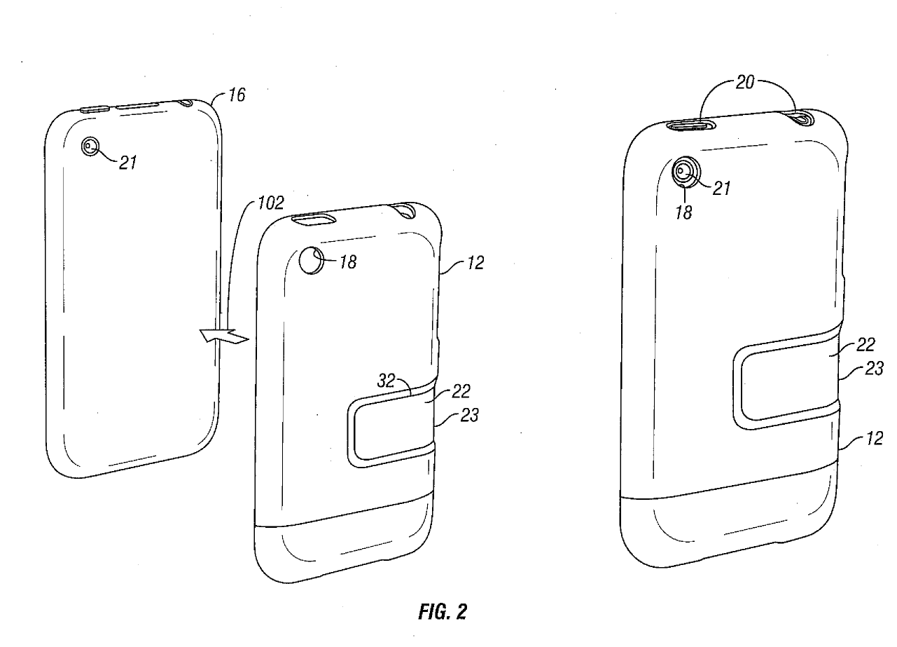

FIGS. 2 through 5 illustrate steps of a method for mounting the hand-held device 16 onto a camera support 26 by way of the case or cover 12 and the coupling device 14. In particular, FIG. 2 illustrates a step 102 of assembling the cover 12 to encapsulate or encompass the hand-held device 16, with opening 18 and 20 providing access to the camera lens 21, or data exchange and audio ports, respectively. While the cover 12 shown in FIG. 2 is a two-piece cover, a single piece snap-on or elastically deformable cover may equally serve the purpose of the present invention.

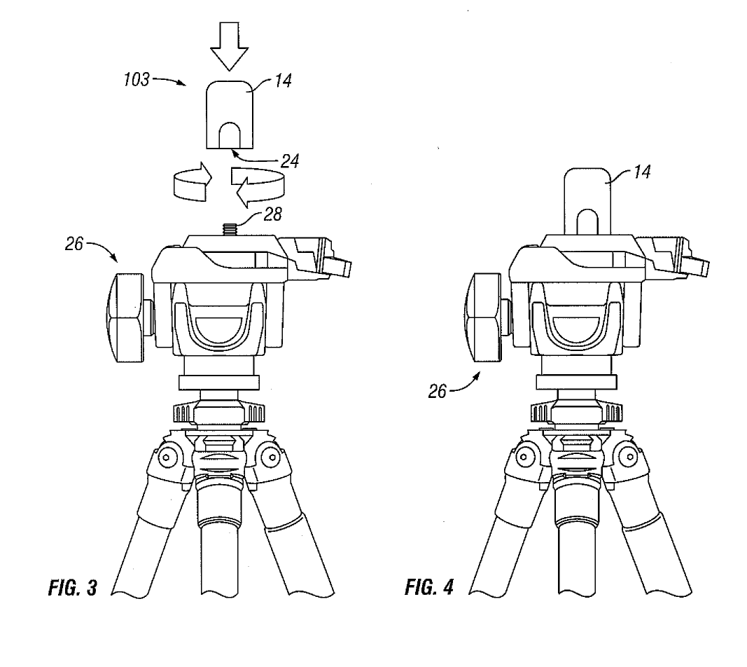

As shown in FIGS. 3 and 4, the coupling device 14 may be mounted upon a tripod head type of camera support 26, via the threaded engagement between the mechanical attachment port 24 and a standard threaded post 28 commonly provided thereon. For example but not by way of limitation, the mechanical attachment port 24 can be ¼-20 female threaded as is common for use with commercial tripod equipment. At a step 103, as shown in FIG. 3, the coupling device 14 is mounted onto the threaded post 28 by way of the mechanical attachment structure 24. Thus, as shown in FIG. 4, the coupling device 14 is secured for movement by the tripod head 26 without fear of inadvertent disengagement.

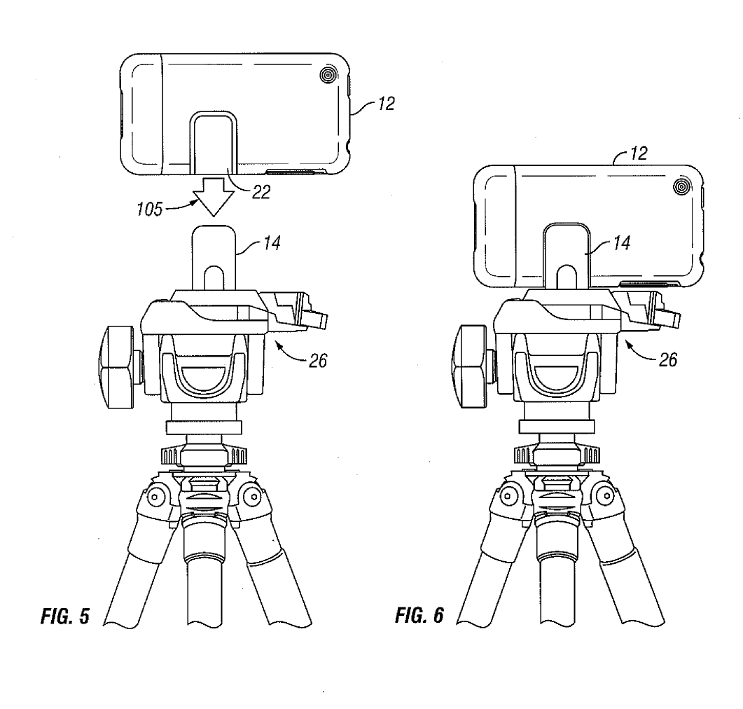

FIGS. 5 and 6 show how the hand-held device 16 may be fastened to the coupling device 14 and the tripod head 26, via the cover 12 and the land 22. As shown in FIG. 5, at a step 105 the land 22 is brought into association with the magnetically active coupling device 14 such that the cover 12, and the encapsulated hand-held device 16, are themselves releasably mounted to the tripod head 26 as shown in FIG. 6.

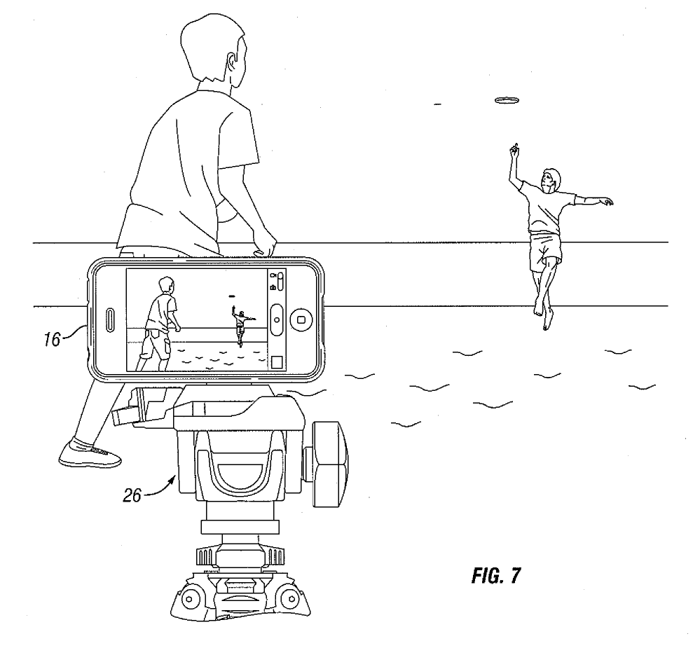

FIG. 7 illustrates the now-mounted hand-held device 16 in use, for capturing a live-action scene for still or real-time video recording.

It is therefore an aspect of the present invention that the magnetically active coupling device 14, and the attractive land 22, may combine to form an easily releasable coupling and accessory system for supporting any known hand-held device, or hand-held electronic device, without the need for any screws, complex platforms, invasive clamps or the like.

It will further be readily appreciated that the present magnetically operable coupling and accessory system 10 gives an operator the ability to couple the hand-held device 16 to a support apparatus, such as the tripod head 26, and therefore avoid the distorting effects of hand or body movement that otherwise may negatively impact the resultant still or live motion video recording accomplished by the hand-held device 16.

While the present invention has been described as comprising a magnetically active coupling device 14, and an attractive land 22, the qualities of these components could well be interchanged with one another, without departing from the broader aspects of the present invention. Thus, the land 22 may instead be formed from a magnetically active material, with the coupling device 14 formed from a ferrous attractive material, without departing from the broader aspects of the present invention.

Returning to FIG. 1, the land 22 is preferably disposed within a depression 30, such that the magnetic attachment of the coupling device 14 creates a smooth and substantially uninterrupted outer surface to the cover 12. Moreover, it is within the scope of the present invention that the case 12 or the coupling device 14 may include ‘wings’, ‘pegs’, or similar enhanced engagement features which provide a structural, as well as magnetic, coupling between the case 12 and the coupling device 14. For example, when the land 22 is disposed within a depression 30 formed on the case 12, as shown in FIGS. 1 and 2, the edges of the depression can act as enhanced engagement features 32. Additionally, as also shown in FIGS. 1 and 2, the land 22 may include a simple curved edge 23 that is convex about one axis for cupped engagement with the coupling device 14 as further discussed below. Similarly, the entire land 22 may be convex or concave about one or two axes in a ‘dimple’, ‘bump’, ‘saddle’ or other complex shape for enhanced engagement with the coupling device 14. As another example of an enhanced engagement feature, the land 22 may be provided with a pattern of distinct magnetically attractive regions having opposing polarities so as to oppose sliding motion of a coupling device 14 having complementary regions of opposing polarities. Also within the scope of the present invention, the land 22 may be magnetically active and substantially planar for ease of sliding disengagement from the coupling device 14.

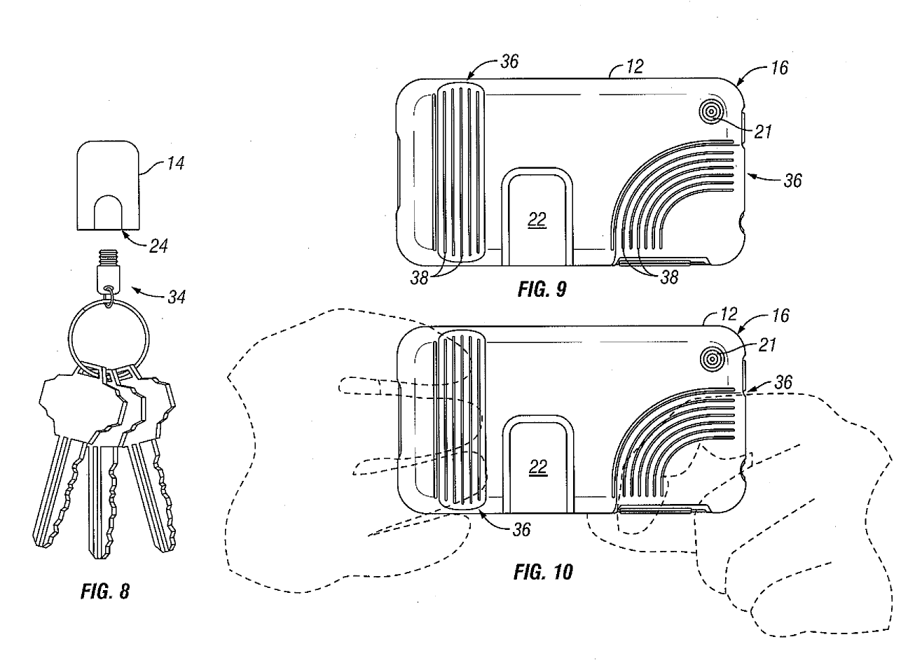

FIG. 8 illustrates one possible accessory use for the mechanical attachment port 24, besides providing a connection to a tripod head 26, as utilized in association with a male threaded key ring component 34, or the like.

FIGS. 9 and 10 illustrate tactile protuberances 36 and surface gradients 38 that may be embossed or otherwise formed, either alone or in combination, on the cover 12, in order to assist an operator in the handling of the device 16, whether attached to a tripod head 26, or not. For example, protuberances 36 may define a curved finger rest or channel adjacent to the camera lens port 18. One purpose of the curved channel is to guide fingers away from the camera lens 21 or equivalent image or audio capturing element, thereby enhancing hand-held use of the device 16 for taking pictures. Another purpose of the finger rest is to provide for an ergonomic grip that may reduce operator fatigue and likewise enhance hand-held use of the device 16. Grooves or stipples 38 may be formed within the curved finger rest for a sure grip on the cover 12 and on the hand-held device 16. A linear finger grip may be formed opposite the curved finger rest to assist in two-handed grasp of the device 16 within the cover 12.

As described herein, the coupling device 14 may be selectively and threadedly attached to a tripod head 26, or other stabilizing mounts, via the mechanical attachment port 24. The present invention is not so limited in this regard, however. That is, with reference once again to FIG. 1, the present invention also contemplates that the rear surface 40 of the coupling device 14 may itself support, define or otherwise evidence alternative attachment structures, for securing the hand-held device 16 for support and stabilization with other structures.

It will therefore be readily appreciated that instead of being smooth in contour (as shown in FIG. 1), the rear surface 40 of the coupling device 14 may evidence a variety of configurations including the construct of additional attachments and devices such as lights, microphones, extensions, and batteries.

It is also within the scope of the present invention that the rear surface 40 of the coupling device 14 may be equipped with a suction cup appendage, a clamping mechanism or a hook and loop means for securing the hand-held device 16 to a variety of surface, such as a window, bicycle handlebars, or fabric.

Thus, whether it is the mechanical attachment port 24, or other means, which are utilized, it will be readily appreciated that the magnetically operable coupling and accessory system 10 provides a quick attachment to both the hand-held device 16 as well as to any suitable supporting structure or mechanism.

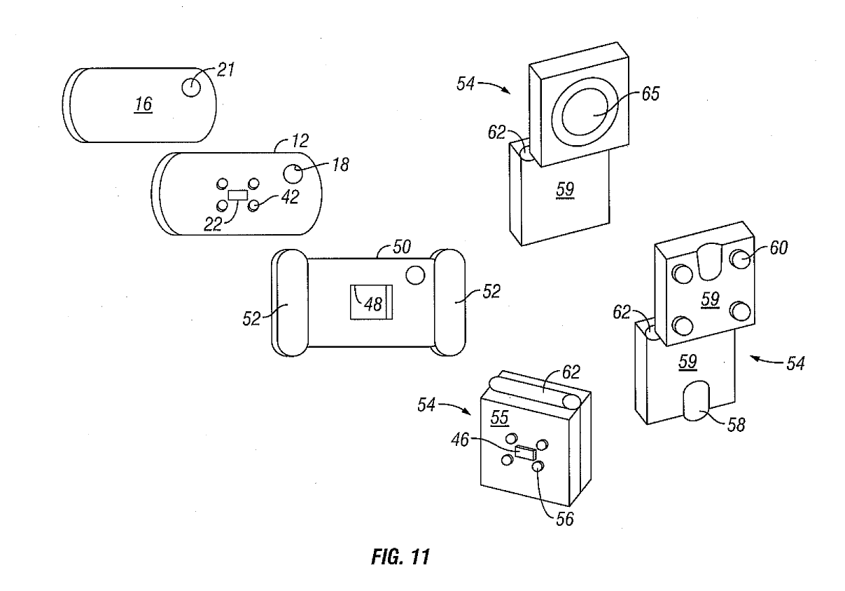

FIG. 11 illustrates several additional and integrated accessory utilizations of the magnetically operable coupling and accessory system, in accordance with yet further alternative embodiments of the present invention.

As shown in FIG. 11, the cover 12 may itself further include one or more depressions, protrusions, and/or slots 42. These depressions and/or slots 42 may be formed in the body of the cover 12, in general, or (with reference to FIG. 1) in the area of the land 22, in particular. In this alternative embodiment, the coupling device 14 would magnetically couple with the land 22 as previously described, however the depressions and/or slots 42 are designed to releasably mate with a corresponding number of matching protrusions formed on the inner surface 46 of the coupling device 14 (as seen in FIG. 1).

As will be appreciated, by forming a corresponding number of matching protrusions on the inner surface 46 of the coupling device 14, the mechanical engagement of magnetic coupling device 14 and the land 22 (or, between the coupling device 14 and the portion of the cover 12 having the one or more depressions and/or slots 42) is made more secure. That is, the protrusions and matching depressions/slots 42 act as enhanced engagement features to ensure that the coupling device 14 cannot slide, shear or otherwise disengage from the land 22 (or, cover 12) unless the hand-held device 16 is moved in the direction of a single axis, i.e., in a direction generally orthogonal to their common mating plane.

FIG. 11 illustrates a particular alternative embodiment, in this regard, in which access to the one or more depressions and/or slots 42 may be effectuated through an opening 48 in an overcase 50. As shown in FIG. 11, the cover 12 supports the one or more depressions and/or slots 42, while the form-fitting, preferably silicon (or the like) overcase 50 defines the opening 48 to provide access to the same. It will be readily appreciated that access to the depressions and/or slots 42 and to the land 22 are requisite elements of any overcase 50, so that accessories for use with the cover 12 may have unencumbered coupling device access.

As further shown in FIG. 11, the overcase 50 may also evidence graspable handles 52 to assist the operator in directing the hand-held device 16, whether attached to a separate supporting structure or accessory, or not.

As discussed previously, the coupling device 14 need not have the structure as shown in FIG. 1. For example, as shown in FIG. 11, a coupling device 54 may include on its forward face 55 a plurality of matching protrusions 56 with which to selectively and releasably mate with the depressions and/or slots 42 formed on the cover 12, either directly or via opening 48 of the overcase 50. A mechanical attachment port 58 may also be provided in the coupling device 54, for selective engagement with a tripod head 26, or the like.

Further refinement of the present invention may also be seen in FIG. 11, in which an upper portion of a rear surface 59 of the coupling device 54 may support any number of useful constructs, such as a lighting module including one or more lights (LED's or the like) 60 or similar devices for providing a momentary or continuous addition to ambient light. For compactness, the upper and lower portions of the coupling device 54 may be rotationally operable with respect to one another via a biased rotation joint 62. In this manner, not only can the hand-held device 16 be releasably affixed to the coupling device 54, and the coupling device secured to a support structure (such as a tripod head 26), but the rotation of the upper and lower portions of the coupling device 54 can alternately protect and reveal the lights 60, so as to increase the range of utility and picture quality of the hand-held device 16.

Similar to the previously discussed embodiment, the rear surface 59 of the coupling device 54 may instead support, define or otherwise evidence alternative attachment structures, for securing the hand-held device 16 for support and stabilization with structures other than the primary intended support 26. It will be readily appreciated, for example, that instead of supporting the lighting module 60, the rear surface 59 may include a hook and loop appendage so as to enable the coupling device 54 to be mounted to any fabric or clothing, thus supporting the hand-held device 16 in that manner. It is also within the scope of the present invention that the rear surface 59 of the coupling device 54 may be equipped with a suction cup appendage 65 for securing the hand-held device 16 to a smooth surface, such as a window, car window, wall, or the like. Indeed, various appendages or accessories may be removably fastened within a part of the coupling device 54, for example, within the hinge-connected part, so as to provide interchangeable rear surfaces 59 having distinct utility.

Thus, whether it is the mechanical attachment port 58, or other means, which are utilized, it will be readily appreciated that the magnetically operable coupling and accessory system 10 provides a quick attachment to both the hand-held device 16 as well as to any suitable supporting structure 26.

Moreover, it will be readily appreciated that the security of the magnetic coupling device between the coupling device 14 (54) and the land 22 (cover 12) is dramatically increased through the use of a mechanical interface illustrated herein by protrusions 56, formed on the coupling device 14 (54), with which to mate with the depressions and/or slots 42, formed on the land 22, or cover 12. Of course, the coupling device 14 (54) may itself define the depressions and/or slots 42, while the land 22 (or cover 12) may instead define the protrusions 56, without departing from the broader aspects of the present invention.

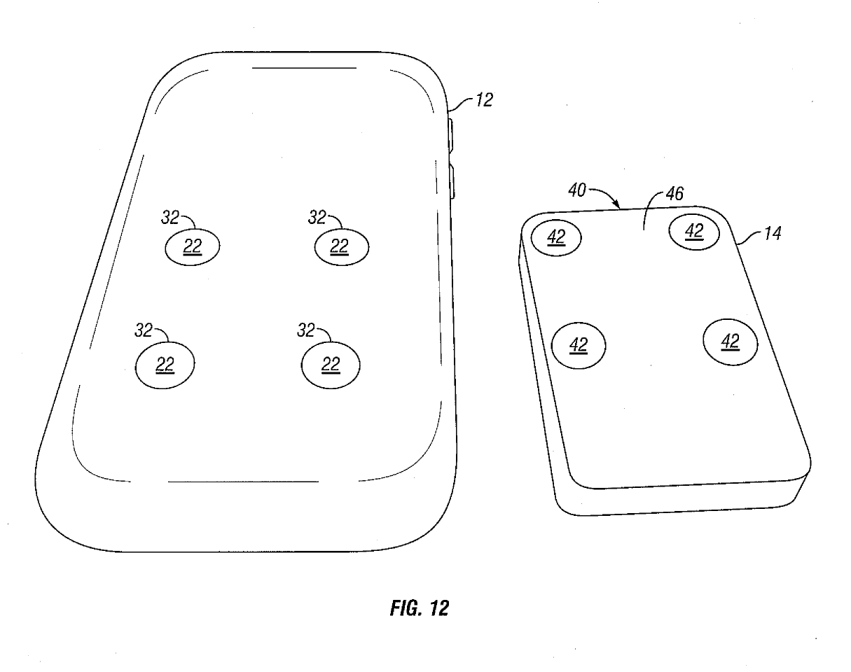

As another example, shown in FIG. 12, the cover 12 may include multiple protruding lands 22, while the back surface 46 of the coupling device 14 may include multiple corresponding depressions 42, which receive the lands 22 and encompass edges 32 of the lands 22 so as to magnetically and mechanically engage the coupling device 14 with the cover 12. Alternatively the protruding lands 22 may be formed directly on the device 16. Thus the lands 22, the depressions or protrusions 42, and the protrusions 56 need not be distinct structures but can be combined in various ways.

While the invention has been described with reference to the preferred embodiments, it will be understood by those skilled in the art that various obvious changes may be made, and equivalents may be substituted for elements thereof, without departing from the essential scope of the present invention. Therefore, it is intended that the invention not be limited to the particular embodiments disclosed, but that the invention includes all equivalent embodiments.

What is claimed is:

1. A coupling and accessory system for an electronic device, comprising:
an enclosure configured to encompass at least a portion of said electronic device and having at least one area defined thereon, wherein said area is a magnetically active region or a magnetically attractive region; and
a coupling device, said coupling device having at least one of a magnetically active region or a magnetically attractive region corresponding to the at least one area of the enclosure, such that said enclosure and said coupling device are magnetically attracted to one another when said enclosure is brought into close association with said coupling device,
wherein said enclosure and coupling device may be mechanically engaged so as to inhibit a sliding disengagement of said enclosure from said coupling device when said enclosure and said coupling device are magnetically attached to one another.

2. The coupling and accessory system according to claim 1, wherein
said mechanical engagement is formed by at least one recess of the mechanically active or attractive region in either the enclosure or the coupling device and at least one protrusion of the corresponding active or attractive region in either the enclosure or the coupling device such that said recess and said protrusion engage mechanically to prohibit the lateral disengagement of the enclosure from the coupling device.

3. The coupling and accessory system according to claim 2, wherein
said recess and said protrusion are shaped in such a manner as to hold said coupling device and said enclosure in a selected one of one or more predetermined orientations relative to each other.

4. The coupling and accessory system according to claim 2, wherein said at least one recess and at least one protrusion include a plurality of recesses and a plurality of complementary protrusions disposed so as to prevent mutual sliding and so as to prevent mutual rotation of said enclosure and said coupling device.

5. The coupling and accessory system according to claim 1, wherein
said coupling device includes a means for mounting said coupling device to a camera support device.

6. The coupling and accessory system according to claim 5, wherein
said camera support device is one of a bipod, tripod, tripod head, monopod, pedestal, shoulder support, handgrip, pole, gantry, or similar devices commonly used for holding or stabilizing an imaging device.

7. The coupling and accessory system according to claim 1, further comprising:
a mechanical attachment structure for mounting said coupling device to a camera support device.

8. The coupling and accessory system according to claim 1, wherein said coupling device is adapted to interchangeably receive any one of a lighting module, a suction cup module, a mechanical attachment structure, or a hook-and-loop fastener module.

9. The coupling and accessory system according to claim 1, wherein said coupling device includes a lighting module.

10. A case for a handheld device, said case including an aperture for providing access to a magnetically active or attractive area formed on an enclosure of said handheld device, and for receiving a coupling device containing a magnetically active or attractive area so as to engage the device to the coupling device via the aperture formed in said case.

11. The case according to claim 10, wherein
the case has an opening for a camera lens.

12. The case according to claim 11, wherein
the case features a channel or ridge disposed at a predetermined location for preventing smudging or abrasion of said camera lens.

13. The case according to claim 10, wherein the case includes a flexible rim for encompassing a portion of said enclosure.

14. A coupling and accessory system for a handheld device, comprising:
an enclosure configured to encompass at least a portion of said electronic device and having at least one area defined thereon, wherein said area is a magnetically active region or a magnetically attractive region;
a coupling device, said coupling device having at least one of a magnetically active region or a magnetically attractive region corresponding to the at least one area of the enclosure, such that said enclosure and said coupling device are magnetically attracted to one another when said enclosure is brought into close association with said coupling device; and
a case interposed between said enclosure and said coupling device, and including an aperture aligned with said magnetically active or attractive area on said enclosure, and aligned with said magnetically active or attractive area of said coupling device,
wherein said enclosure and said coupling device are mechanically engaged via said aperture of said case so as to capture said case and to inhibit a sliding disengagement of said enclosure from said coupling device when said enclosure and said coupling device are magnetically attached to one another.

15. The system according to claim 14, wherein said handheld device includes at least one of a display or a lens, said enclosure includes a first opening aligned with said at least one of a display or a lens, said flexible case includes a second opening aligned with said first opening, and said coupling device includes a mechanical attachment structure for attachment to said support device.

16. A method for mounting a handheld device to a support, comprising:
providing an enclosure configured to encompass at least a portion of said electronic device and having at least one area defined thereon, wherein said area is a magnetically active region or a magnetically attractive region;
encompassing said device within said enclosure;
providing a magnetic coupling device, which includes a mechanical attachment structure;
fastening said mechanical attachment structure to said support; and
magnetically attaching said enclosure to said magnetic coupling device.

17. The method according to claim 16, further comprising:
selecting said magnetic coupling device from a plurality of interchangeable coupling devices including at least two of a light-supporting coupling device, a suction cup coupling device, and a hook-and-loop fastener coupling device.

18. The method according to claim 16, further comprising:
pre-configuring said magnetic coupling device by installing onto said magnetic coupling device one of a lighting module, a suction cup module, or a hook-and-loop fastener module.

19. The method according to claim 16, further comprising:
pre-configuring said magnetic coupling device by installing onto said magnetic coupling device a mechanical attachment structure corresponding to said support.

20. The method according to claim 16, wherein said support is one of a bipod, tripod, tripod head, monopod, pedestal, shoulder support, handgrip, pole, gantry, or similar devices commonly used for holding or stabilizing an imaging device.

21. An enclosure for connecting an electronic device with a complementary coupling device, comprising:
an enclosure configured to encompass at least a portion of said electronic device; and
at least one area defined on said enclosure, wherein said area is a magnetically active region or a magnetically attractive region for magnetic attachment to a corresponding magnetically attractive region or magnetically active region of a complementary coupling device.

22. The enclosure according to claim 21, wherein said area is a substantially planar surface.

23. The enclosure according to claim 21, wherein said area includes a surface curved about at least one axis substantially parallel to said surface.

24. The enclosure according to claim 21, wherein said area includes at least one enhanced engagement feature for restraining sliding motion of a mating structure across said area.

25. The enclosure according to claim 24, wherein said at least one enhanced engagement feature is selected from one of a dimple, a bump, a stud, a protrusion, a depression, a slot, a curved surface, or a pattern of magnetically attractive regions.

26. A coupling device for use with a complementary enclosure, said coupling device comprising:
a mechanical attachment structure; and
a magnetically active or magnetically attractive surface connected with said mechanical attachment structure, said region including at least one enhanced engagement feature for restraining sliding motion of said complementary enclosure.

27. The coupling device as claimed in claim 26, wherein said mechanical attachment structure is adapted for attaching said coupling device to a camera support device.

28. The coupling device as claimed in claim 26, wherein said camera support device is one of a bipod, tripod, tripod head, monopod, pedestal, shoulder support, handgrip, pole, gantry, or similar devices commonly used for holding or stabilizing an imaging device.

29. The coupling device as claimed in claim 26, wherein said at least one enhanced engagement feature is selected from one of a dimple, a bump, a stud, a protrusion, a depression, a slot, a curved surface, or a pattern of magnetically attractive regions.

30. The coupling device as claimed in claim 26, wherein said magnetically active or magnetically attractive surface is not bounded within a single plane.
